(19) United States
(12) Patent Application Publication
(10) Pub. No.: US 2025/0364042 A1
(43) Pub. Date: Nov. 27, 2025

(54) MEMORY CELL INCLUDING A READ CIRCUIT

(71) Applicant: Microsemi SoC Corp., Chandler, AZ (US)

(72) Inventors: John Lynn McCollum, Orem, UT (US); Fethi Dhaoui, Mesa, AZ (US)

(73) Assignee: Microsemi SoC Corp., Chandler, AZ (US)

(21) Appl. No.: 18/936,166

(22) Filed: Nov. 4, 2024

Related U.S. Application Data
(60) Provisional application No. 63/651,551, filed on May 24, 2024.

(51) Int. Cl. G11C 11/419

(52) U.S. Cl. CPC G11C 11/419

(57) ABSTRACT

A memory cell may include a word write line, a first bit line, a first storage node, a second storage node, a first passgate transistor, and a read circuit. A gate of the first passgate transistor may be electrically connected to the word write line. A source of the first passgate transistor may be electrically connected to the first bit line. A drain of the first passgate transistor may be electrically connected to one of the first and second storage nodes. The read circuit may include a word read line, a first read transistor, and a second read transistor. A gate of the first read transistor may be electrically connected to the first storage node. A gate of the second read transistor may be electrically connected to the word read line. A drain of the first read transistor may be electrically connected to the second read transistor.

### CROSS-REFERENCE TO RELATED APPLICATIONS

The current patent application claims the benefit under 35 U.S.C. § 119 (e) of the priority date of U.S. Provisional Application Ser. No. 63/651,551; titled “LOW POWER COMPACT FPGA CONFIGURATION MEMORY”; and filed May 24, 2024. The Provisional Application is hereby incorporated by reference, in its entirety, into the current patent application.

### TECHNICAL FIELD

Various examples of the present disclosure relate to a memory cell including a dedicated read circuit.

### BACKGROUND

Static random access memory (SRAM) cells are commonly used with reprogrammable devices, such as field-programmable gate arrays (FPGAs). Read disturb errors may occur when data is read from a SRAM memory cell for various reasons. A read disturb error may cause the data stored in the SRAM memory cell to change when the data is read. Read disturb errors may be caused by signal leakage between circuit components of the SRAM memory cell.

This background discussion is intended to provide information related to the present invention which is not necessarily prior art.

### SUMMARY OF THE INVENTION

According to various examples of the present disclosure, a memory cell may be provided. The memory cell may include a word write line, a first bit line, a first storage node, a second storage node, a first passgate transistor, and a read circuit. The first passgate transistor includes a gate terminal, a source terminal, and a drain terminal. The gate terminal of the first passgate transistor may be electrically connected to the word write line. The source terminal of the first passgate transistor may be electrically connected to the first bit line. The drain terminal of the first passgate transistor may be electrically connected to one of the first and second storage nodes. The read circuit may include a word read line, a first read transistor, and a second read transistor. The first and second read transistors include respective gate, source and drain terminals. The gate terminal of the first read transistor may be electrically connected to the first storage node. The gate terminal of the second read transistor may be electrically connected to the word read line. The drain terminal of the first read transistor may be electrically connected to the source terminal of the second read transistor.

According to various examples of the present disclosure, a method may be provided. A word write line may activate a first passgate transistor of a memory cell. The first passgate transistor may have a drain terminal electrically connected to a first storage node of the memory cell. A first bit line of the memory cell may write data to the first storage node. The first storage node may be electrically connected to a read circuit of the memory cell. The read circuit may include a first read transistor and a second read transistor. A drain terminal of the first read transistor may be electrically connected to a source terminal of the second read transistor. A word read line of the memory cell may activate the second read transistor of the read circuit. The data may be read from the first storage node.

According to various examples of the present disclosure, a memory cell may be provided. The memory cell may include a first intermediate node, a second intermediate node, a write circuit, a read circuit, a first voltage rail, a second voltage rail, a first storage node, a second storage node, a first pair of p-channel transistor, a second pair of p-channel transistors, a first pair of n-channel transistors, and a second pair of n-channel transistors. The write circuit may include a write word line, a write transistor, and a bit write line. The write transistor may be electrically connected between the bit write line and the first intermediate node. The read circuit may include a read transistor, a word read line, and a bit read line. The read transistor may be electrically connected between the bit read line and the second intermediate node. The first pair of p-channel transistors may be electrically connected in series between the first voltage rail and the first storage node. A drain terminal of a first p-channel transistor of the first pair of p-channel transistors may be electrically connected to a source terminal of a second p-channel transistor of the first pair of p-channel transistors to define the first intermediate node. The second pair of p-channel transistors may be electrically connected in series between the first voltage rail and the second storage node. The first pair of n-channel transistors may be electrically connected in series between the first storage node and the second voltage rail. A drain terminal of a first n-channel transistor of the first pair of n-channel transistors may be electrically connected to a source terminal of a second n-channel transistor of the first pair of n-channel transistors to define the second intermediate node. The second pair of n-channel transistors may be electrically connected in series between the second storage node and the second voltage rail.

### BRIEF DESCRIPTION OF THE DRAWINGS

FIG. 1 illustrates an example twelve transistor (12T) memory cell having a dedicated read circuit;

FIG. 2 illustrates another example twelve transistor (12T) memory cell having a dedicated read circuit;

FIG. 3 illustrates an example nine transistor (9T) memory cell having a dedicated read circuit;

FIGS. 4A-4D illustrate various example read circuits of the memory cells of FIGS. 1-3;

FIG. 5 illustrates an example ten transistor (10T) memory cell having a dedicated read circuit; and

FIG. 6 illustrates an example method performed by the memory cells of FIGS. 1-3 and 5.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, operations, features, functions, or the like.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Various examples of the present disclosure relate to a memory cell including a dedicated read circuit. In various examples, the memory cell may be a static random access memory (SRAM) cell for use with a reprogrammable device, such as a field-programmable gate array (FPGA). An output of the memory cell may be used to selectively connect one signal with another in the programmable routing of the FPGA.

The memory cell of the present disclosure includes a dedicated read circuit. The dedicated read circuit includes a pair of series connected transistors and word read line. The word read line may be used for read operations. The dedicated read circuit may reduce read disturb errors by providing an independent means to read data stored in the memory cell. Further, separating read and write access to the memory cell may enable background read repair and enable data to be written to or read from the memory cell at any time. The read and write operations may be independent of each other. The memory cell may additionally include cascoded pull-up and pull-down transistors. The cascoded transistors may reduce static power consumption of the memory cell by ensuring that a voltage across the cascoded transistors is less than a voltage across a transistor writing data to the memory cell or reading data from the memory cell.

In various examples, two transistors may be electrically connected in series when a drain terminal of a first transistor is electrically connected to a source terminal of a second transistor.

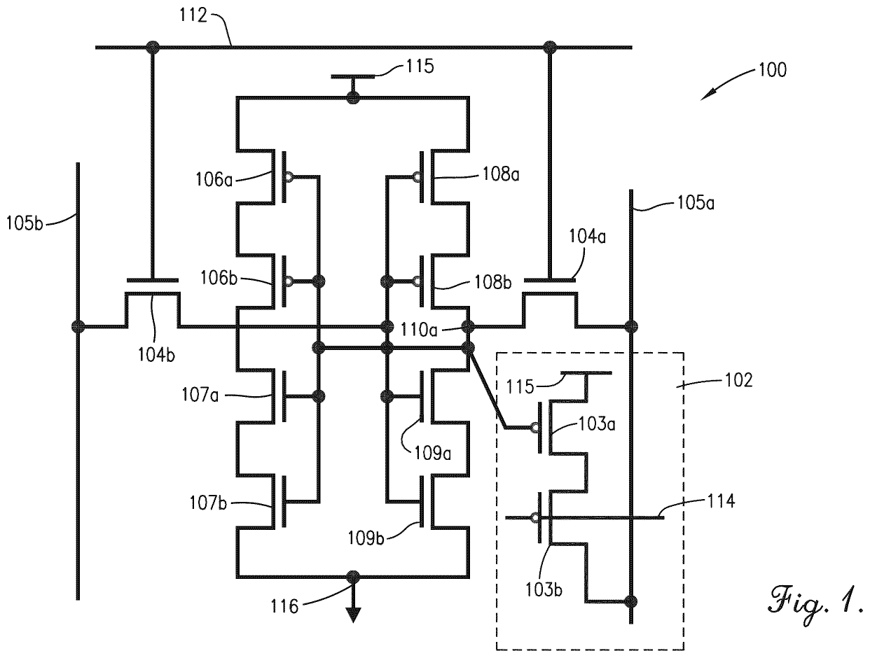

FIG. 1 illustrates an example twelve transistor (12T) memory cell 100 including a dedicated read circuit 102. The 12T memory cell 100 additionally includes first and second passgate transistors 104a, 104b, first and second bit lines 105a, 105b, a first pair of p-channel transistors 106a, 106b, a first pair of n-channel transistors 107a, 107b, a second pair of p-channel transistors 108a, 108b, a second pair of n-channel transistors 109a, 109b, first and second storage nodes 110a, 110b, a word write line 112, a word read line 114, a first voltage rail 115, and a second voltage rail 116. In various examples, data may be written to the first and second storage nodes 110a, 110b. The data may be read by the read circuit 102. The data may have a logic high value or a logic low value. The logic high value may correspond to a binary bit value of 1. The logic low value may correspond to a binary bit value of 0.

The first passgate transistor 104a includes drain and source terminals electrically connected between the first storage node 110a and the bit line 105a. The second passgate transistor 104b includes drain and source terminals electrically connected between the second storage node 110b and the bit line 105b. Respective gate terminals of the first and second passgate transistors 104a, 104b are electrically connected to the word write line 112. In various examples, when activated, the first and second passgate transistors 104a, 104b may be operable to pass data from the bit lines 105a, 105b to the storage nodes 110a, 110b, respectively. The word write line 112 may activate the first passgate transistor 104a to write data to the storage node 110a, and may activate the second passgate transistor 104b to store data in the second storage node 110b.

The first pair of p-channel transistors 106a, 106b are electrically connected in series between the first voltage rail 115 and the second storage node 110b. The first pair of n-channel transistors 107a, 107b are electrically connected in series between the second storage node 110b and the second voltage rail 116. A drain terminal of the p-channel transistor 106a is electrically connected to a source terminal of the p-channel transistor 106b. A source terminal of the p-channel transistor 106a is electrically connected to the voltage rail 115. The first pair of n-channel transistor 107a, 107b are electrically connected to each other in series. A source terminal of the n-channel transistor 107a is electrically connected to a drain terminal of the n-channel transistor 107b. A source terminal of the n-channel transistor 107b is electrically connected to the voltage rail 116. A drain terminal of the p-channel transistor 106b is electrically connected to a drain terminal of the n-channel transistor 107a to define the second storage node 110b.

The second pair of p-channel transistors 108a, 108b are electrically connected in series between the first voltage rail 115 and the first storage node 110a. The second pair of n-channel transistors 109a, 109b are electrically connected in series between the first storage node 110a and the second voltage rail 116. A drain terminal of the p-channel transistor 108a is electrically connected to a source terminal of the p-channel transistor 108b. A source terminal of the p-channel transistor 108a is electrically connected to the voltage rail 115. The second pair of n-channel transistors 109a, 109b are electrically connected to each other in series. A source terminal of the n-channel transistor 109a is electrically connected to a drain terminal of the n-channel transistor 109b. A source terminal of the n-channel transistor 109b is electrically connected to the voltage rail 116. A drain terminal of the p-channel transistor 108b is electrically connected to a drain terminal of the n-channel transistor 109a to define the first storage node 110a.

In various examples, respective gate terminals of the first pair of p-channel transistors 106a, 106b and the first pair of n-channel transistors 107a, 107b are electrically connected together and electrically connected to the first storage node 110a. Respective gate terminals of the second pair of p-channel transistors 108a, 108b and the second pair of n-channel transistors 109a, 109b are electrically connected together and electrically connected to the second storage node 110b.

When data is written to the first storage node 110a, the data may cause either the first pair of p-channel transistors 106a, 106b or the first pair of n-channel transistors 107a, 107b to be activated. In an example, the passgate transistor 104a may write data to the first storage node 110a. When the data has the logic low value, the p-channel transistors 106a, 106b may be activated and the n-channel transistors 107a, 107b may be deactivated. When the data has the logic high value, the n-channel transistors 107a, 107b may be activated and the p-channel transistors 106a, 106b may be deactivated. When the p-channel transistors 106a, 106b are activated, data having a logic high value may be passed from the voltage rail 115 to the storage node 110b. When the n-channel transistors 107a, 107b are activated, data having the logic low value may be passed from the voltage rail 116 to the storage node 110b.

When data is written to the second storage node 110b by the second passgate transistor 104b, the data may cause either the second pair of p-channel transistors 108a, 108b or the second pair of n-channel transistors 109a, 109b to be activated. Accordingly, the data stored in the storage nodes 110a, 110b may have complementary values. When the data has the logic low value, the p-channel transistors 108a, 108b may be activated and the n-channel transistors 109a, 109b may be deactivated. When the data has the logic high value, the n-channel transistors 109a, 109b may be activated and the p-channel transistors 108a, 108b may be deactivated. When the p-channel transistors 108a, 108b are activated, data having a logic high value may be passed from the voltage rail 115 to the storage node 110a. When the n-channel transistors 109a, 109b are activated, data having the logic low value may be passed from the voltage rail 116 to the storage node 110a. Accordingly, only one of the passgate transistors 104a, 104b is required to write data to both of the storage nodes 110a, 110b.

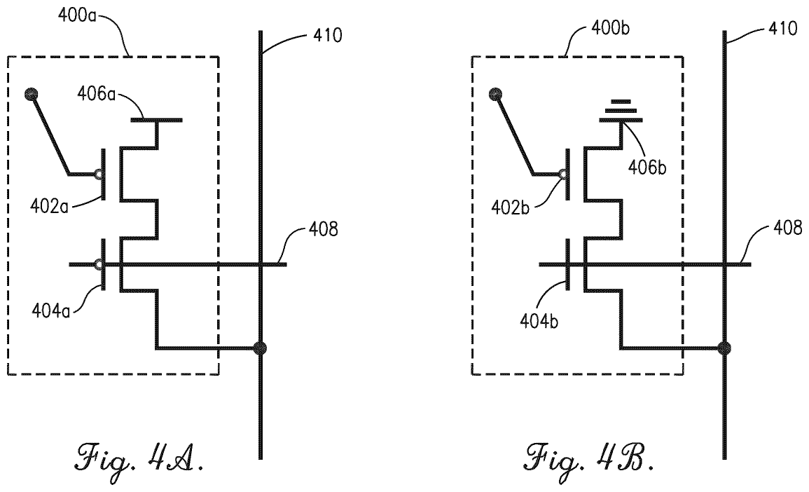

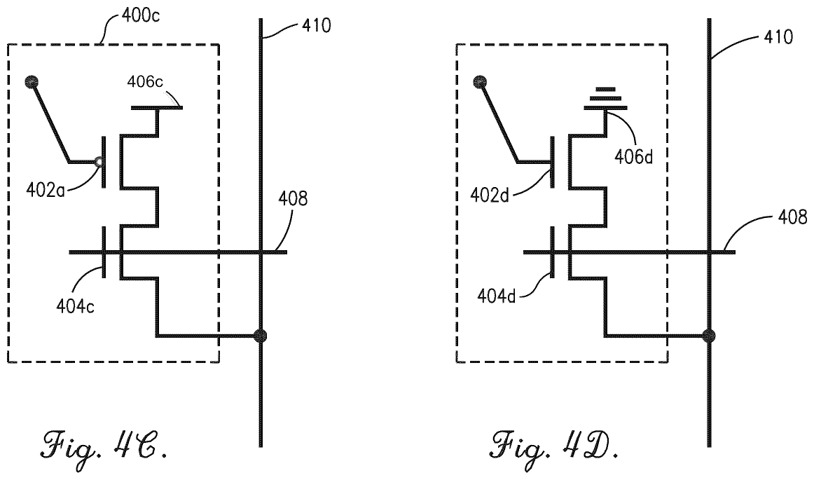

In various examples, the read circuit 102 includes a first read transistor 103a and a second read transistor 103b. The first and second read transistors 103a, 103b may be electrically connected together in series. A source terminal of the first read transistor 103a may be electrically connected to the voltage rail 115. The voltage rail 115 may provide one of a supply voltage Vdd and a ground voltage to the first read transistor 103a, as discussed below with reference to FIGS. 4A-4D. A gate terminal of the second read transistor 103b may be electrically connected to the word read line 114. A drain terminal of the second read transistor 103b may be electrically connected to the bit line 105a.

The first read transistor 103a may be activated or deactivated depending on a value of the data stored in the first storage node 110a. In an example, the first read transistor 103a may be a p-channel transistor. The first read transistor 103a may be activated when data having the logic low value is stored in the first storage node 110a. The first read transistor 103a may be deactivated when data having the logic high value is stored in the first storage node 110a. The second read transistor 103b may be activated to read the data from the first storage node 110a. The second read transistor 103b may pass the data to the bit line 105a. The bit line 105a may connect the signal to another device, such as another memory cell or an FPGA.

The second read transistor 103b may pass data having a logic high value when the first read transistor 103a is deactivated. The second read transistor 103b may pass data having the logic low value when the read transistor 103a is activated. Accordingly, the data may be read based on whether the first read transistor 103a is activated or deactivated. Advantageously, data may be read from the first storage node 110a without disturbing the first storage node 110a. In various examples, because the data stored in the first and second storage nodes 110a, 110b has complementary values, data read from the storage node 110a may be used to determine the value of the data stored in the second storage node 110b. Accordingly, only the data from the first storage node 110a needs to be read to determine the value of the data stored in both storage nodes 110a, 110b.

In various examples, each of the p-channel transistors 106a, 106b, 108a, 108b, the n-channel transistors 107a, 107b, 109a, 109b, passgate transistors 104a, 104b, and read transistors 103a, 103b may occupy about 3 nm of space when disposed on a die, without limitation. The passgate transistors 104a, 104b may each occupy a die area of 3 nm. The first pair of p-channel transistors 106a, 106b may occupy a die area of 3 nm each, or 6 nm total. The second pair of p-channel transistors 108a, 108b may occupy a die area of 3 nm each, or 6 nm total. The first pair of n-channel transistors 107a, 107b may occupy a die area of 3 nm each, or 6 nm total. The second pair of n-channel transistors 109a, 109b may occupy a die area of 3 nm each, or 6 nm total. It would be appreciated by one of ordinary skill in the art that the transistors may occupy more or less die area, depending on a type of transistor that is used.

In various examples, the logic high value may correspond to a voltage Vdd. In various examples, the voltage Vdd may be 0.7V, 0.6V, 0.5V, or 0.4V, without limitation. A threshold voltage of each of the p-channel transistors 106a, 106b, 108a, 108b, the n-channel transistors 107a, 107b, 109a, 109b, passgate transistors 104a, 104b, and read transistors 103a, 103b may be selected based on a desired value of the voltage Vdd. In an example, when Vdd is 0.4V, the threshold voltage may be around 0.15V, without limitation.

In various examples, when either of the passgate transistors 104a, 104b are driven, the current passing through the passgate transistors 104a, 104b may overpower any current flowing through the p-channel transistors 106a, 106b, 108a, 108b or the n-channel transistors 107a, 107b, 109a, 109b, which may allow data to be stored in the storage nodes 110a, 110b while preventing leakage between the various transistors of the 12T memory cell 100. The series arrangement of the p-channel transistors 106a, 106b, 108a, 108b, and the n-channel transistors 107a, 107b, 109a, 109b may be referred to as a cascoded scheme. The cascoded scheme of the transistors may prevent signal leakage and reduce static power consumption.

In various examples, the first storage node 110a and the second storage node 110b may store complementary values. For example, when the data stored in the first storage node 110a is the logic high value, the data stored in the second storage node may be the logic low value, as described above. Data may be written to the storage nodes 110a, 110b at any time and without restriction due to the word write line 112 being independent of the word read line 114. The read circuit 102 may enable a read operation to be performed independently of a write operation. Separation of the read and write operations may enable the read operations and write operations to be performed any time, without limitation. It would be appreciated by one of ordinary skill in the art that the read circuit 102 may be electrically connected to either the first storage node 110a or the second storage node 110b without departing from the scope of the present disclosure.

In various examples, the read circuit 102 may enable data to be read from the first storage node 110a and the second storage node 110b at any time independently of any write operations. Separation of the write operations and read operations may enable data to be read from the first storage node 110a and the second storage node 110b without disturbing the first storage node 110a or the second storage node 110b. Additionally, the inclusion of the dedicated read circuit 102 may enable detection of read disturb at the first storage node 110a and second storage node 110b and enable background read and repair of the 12T memory cell 100 when read disturb is detected.

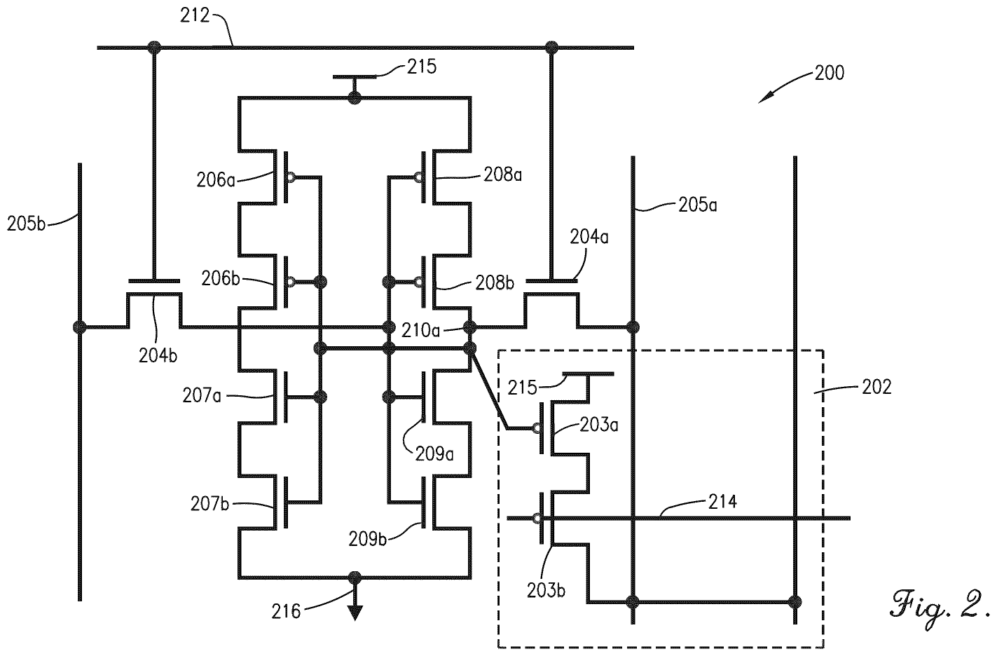

FIG. 2 illustrates an example twelve transistor (12T) memory cell 200 including a dedicated read circuit 202. The 12T memory cell 200 additionally includes first and second passgate transistors 204a, 204b, bit lines 205a, 205b, 205c, a first pair of p-channel transistors 206a, 206b, a first pair of n-channel transistors 207a, 207b, a second pair of p-channel transistors 208a, 208b, a second pair of n-channel transistors 209a, 209b, first and second storage nodes 210a, 210b, a word write line 212, a word read line 214, a first voltage rail 215, and a second voltage rail 216. In various examples, data may be written to the first and second storage nodes 210a, 210b. The data may be read by the read circuit 202. The data may have a logic high value or a logic low value. The logic high value may correspond to a binary bit value of 1. The logic low value may correspond to a binary bit value of 0.

The first passgate transistor 204a includes drain and source terminals electrically connected between the first storage node 210a and the bit line 205a. The second passgate transistor 204b includes drain and source terminals electrically connected between the second storage node 210b and the bit line 205b. Respective gate terminals of the first and second passgate transistors 204a, 204b are electrically connected to the word write line 212. In various examples, when activated, the first and second passgate transistors 204a, 204b may be operable to pass data from the bit lines 205a, 205b to the storage nodes 210a, 210b, respectively. The word write line 212 may activate the first passgate transistor 204a to write data to the storage node 210a, and may activate the second passgate transistor 204b to store data in the second storage node 210b.

The first pair of p-channel transistors 206a, 206b are electrically connected in series between the first voltage rail 215 and the second storage node 210b. The first pair of n-channel transistors 207a, 207b are electrically connected in series between the second storage node 210b and the second voltage rail 216. A drain terminal of the p-channel transistor 206a is electrically connected to a source terminal of the p-channel transistor 206b. A source terminal of the p-channel transistor 206a is electrically connected to the voltage rail 215. The first pair of n-channel transistor 207a, 207b are electrically connected to each other in series. A source terminal of the n-channel transistor 207a is electrically connected to a drain terminal of the n-channel transistor 207b. A source terminal of the n-channel transistor 207b is electrically connected to the voltage rail 216. A drain terminal of the p-channel transistor 206b is electrically connected to a drain terminal of the n-channel transistor 207a to define the second storage node 210b.

The second pair of p-channel transistors 208a, 208b are electrically connected in series between the first voltage rail 215 and the first storage node 210a. The second pair of n-channel transistors are electrically connected in series between the first storage node 210a and the second voltage rail 216. A drain terminal of the p-channel transistor 208a is electrically connected to a source terminal of the p-channel transistor 208b. A source terminal of the p-channel transistor 208a is electrically connected to the voltage rail 215. The second pair of n-channel transistors 209a, 209b are electrically connected to each other in series. A source terminal of the n-channel transistor 209a is electrically connected to a drain terminal of the n-channel transistor 209b. A source terminal of the n-channel transistor 209b is electrically connected to the voltage rail 216. A drain terminal of the p-channel transistor 208b is electrically connected to a drain terminal of the n-channel transistor 209a to define the first storage node 210a.

In various examples, respective gate terminals of the first pair of p-channel transistors 206a, 206b and the first pair of n-channel transistors 207a, 207b are electrically connected together and electrically connected to the first storage node 210a. Respective gate terminals of the second pair of p-channel transistors 208a, 208b and the second pair of n-channel transistors 209a, 209b are electrically connected together and electrically connected to the second storage node 210b.

When data is written to the first storage node 210a, the data may cause either the first pair of p-channel transistors 206a, 206b or the first pair of n-channel transistors 207a, 207b to be activated. In an example, the passgate transistor 204a may write data to the first storage node 210a. When the data has the logic low value, the p-channel transistors 206a, 206b may be activated and the n-channel transistors 207a, 207b may be deactivated. When the data has the logic high value, the n-channel transistors 207a, 207b may be activated and the p-channel transistors 206a, 206b may be deactivated. When the p-channel transistors 206a, 206b are activated, data having a logic high value may be passed from the voltage rail 215 to the storage node 210b. When the n-channel transistors 207a, 207b are activated, data having the logic low value may be passed from the voltage rail 216 to the storage node 210b.

When data is written to the second storage node 210b by the second passgate transistor 204b, the data may cause either the second pair of p-channel transistors 208a, 208b or the second pair of n-channel transistors 209a, 209b to be activated. Accordingly, the data stored in the storage nodes 210a, 210b may have complementary values. When the data has the logic low value, the p-channel transistors 208a, 208b may be activated and the n-channel transistors 209a, 209b may be deactivated. When the data has the logic high value, the n-channel transistors 209a, 209b may be activated and the p-channel transistors 208a, 208b may be deactivated. When the p-channel transistors 208a, 208b are activated, data having a logic high value may be passed from the voltage rail 215 to the storage node 210a. When the n-channel transistors 209a, 209b are activated, data having the logic low value may be passed from the voltage rail 216 to the storage node 210a. Accordingly, only one of the passgate transistors 204a, 204b is required to write data to both of the storage nodes 210a, 210b.

In various examples, the read circuit 202 includes a first read transistor 203a and a second read transistor 203b. The first and second read transistors 203a, 203b may be electrically connected together in series. A source terminal of the first read transistor 203a may be electrically connected to a voltage source 215. The voltage rail 215 may provide one of a supply voltage Vdd and a ground voltage to the first read transistor 203a, as discussed below with reference to FIGS. 4A-4D. A gate terminal of the second read transistor 203b may be electrically connected to the word read line 214. A drain terminal of the second read transistor 203b may be electrically connected to the bit line 205c.

The first read transistor 203a may be activated or deactivated depending on a value of the data stored in the first storage node 210a. In an example, the first read transistor 203a may be a p-channel transistor. The first read transistor 203a may be activated when data having the logic low value is stored in the first storage node 210a. The first read transistor 203a may be deactivated when data having the logic high value is stored in the first storage node 210a. The second read transistor 203b may be activated to read the data from the first storage node 210a. The second read transistor 203b may pass the data to the bit line 205c. The bit line 205c may connect the signal to another device, such as another memory cell or an FPGA. The bit line 205c may enable further separation of read and write operations by providing a dedicated bit read line.

The second read transistor 203b may pass data having a logic high value when the first read transistor 203a is deactivated. The second read transistor 203b may pass data having the logic low value when the read transistor 203a is activated. Accordingly, the data may be read based on whether the first read transistor 203a is activated or deactivated. Advantageously, data may be read from the first storage node 210a without disturbing the first storage node 210a. In various examples, because the data stored in the first and second storage nodes 210a, 210b has complementary values, data read from the storage node 210a may be used to determine the value of the data stored in the second storage node 210b. Accordingly, only the data from the first storage node 210a needs to be read to determine the value of the data stored in both storage nodes 210a, 210b.

In various examples, each of the p-channel transistors 206a, 206b, 208a, 208b, the n-channel transistors 207a, 207b, 209a, 209b, passgate transistors 204a, 204b, and read transistors 203a, 203b may occupy about 3 nm of space when disposed on a die, without limitation. The passgate transistors 204a, 204b may each occupy a die area of 3 nm. The first pair of p-channel transistors 206a, 206b may occupy a die area of 3 nm each, or 6 nm total. The second pair of p-channel transistors 208a, 208b may occupy a die area of 3 nm each, or 6 nm total. The first pair of n-channel transistors 207a, 207b may occupy a die area of 3 nm each, or 6 nm total. The second pair of n-channel transistors 209a, 209b may occupy a die area of 3 nm each, or 6 nm total. It would be appreciated by one of ordinary skill in the art that the transistors may occupy more or less die area, depending on a type of transistor that is used.

In various examples, the logic high value may correspond to a voltage Vdd. In various examples, the voltage Vdd may be 0.7V, 0.6V, 0.5V, or 0.4V, without limitation. A threshold voltage of each of the p-channel transistors 206a, 206b, 208a, 208b, the n-channel transistors 207a, 207b, 209a, 209b, passgate transistors 204a, 204b, and read transistors 203a, 203b may be selected based on a desired value of the voltage Vdd. In an example, when Vdd is 0.4V, the threshold voltage may be around 0.15V, without limitation.

In various examples, when either of the passgate transistors 204a, 204b are driven, the current passing through the passgate transistors 204a, 204b may overpower any current flowing through the p-channel transistors 206a, 206b, 208a, 208b or the n-channel transistors 207a, 207b, 209a, 209b, which may allow data to be stored in the storage nodes 210a, 210b while preventing leakage between the various transistors of the 12T memory cell 200. The series arrangement of the p-channel transistors 206a, 206b, 208a, 208b, and the n-channel transistors 207a, 2076, 209a, 209b may be referred to as a cascoded scheme. The cascoded scheme of the transistors may prevent signal leakage and reduce static power consumption.

In various examples, the first storage node 210a and the second storage node 210b may store complementary values. For example, when the data stored in the first storage node 210a is the logic high value, the data stored in the second storage node may be the logic low value, as described above. Data may be written to the storage nodes 210a, 210b at any time and without restriction due to the word write line 212 being independent of the word read line 214. The read circuit 202 may enable a read operation may to be performed independently of a write operation. Separation of the read and write operations may enable the read operations and write operations to be performed any time, without limitation. It would be appreciated by one of ordinary skill in the art that the read circuit 202 may be electrically connected to either the first storage node 210a or the second storage node 210b without departing from the scope of the present disclosure.

In various examples, the read circuit 202 may enable data to be read from the first storage node 210a and the second storage node 210b at any time independently of any write operations. Separation of the write operations and read operations may enable data to be read from the first storage node 210a and the second storage node 210b without disturbing the first storage node 210a or the second storage node 210b. Additionally, the inclusion of the dedicated read circuit 202 may enable detection of read disturb at the first storage node 210a and second storage node 210b and enable background read and repair of the 12T memory cell 200 when read disturb is detected.

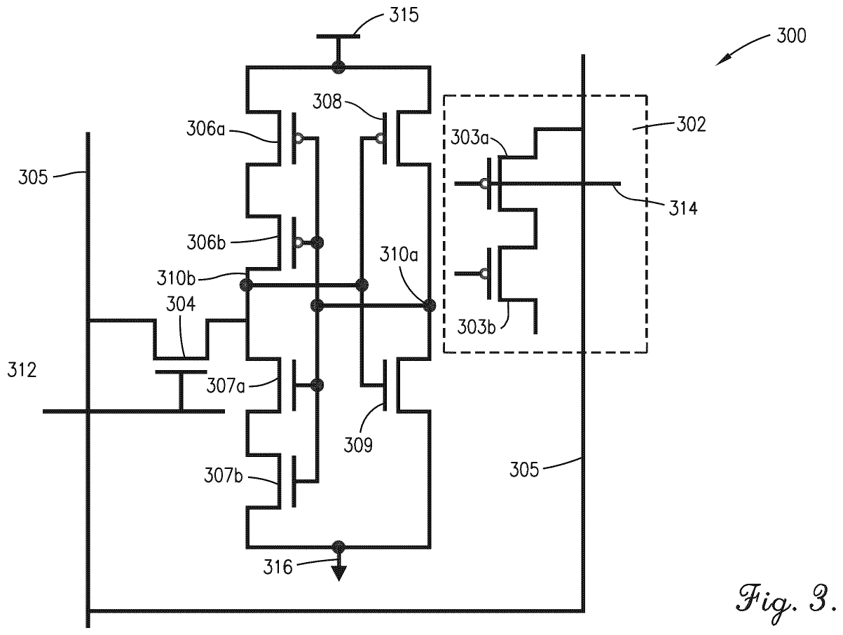

FIG. 3 illustrates an example nine transistor (9T) memory cell 300 including a dedicated read circuit 302. The 9T memory cell 300 additionally includes a passgate transistor 304, a bit line 305, a first pair of p-channel transistors 306a, 306b, a first pair of n-channel transistors 307a, 307b, a third p-channel transistor 308, a third n-channel transistor 309, first and second storage nodes 310a, 310b, a word write line 312, a word read line 314, a first voltage rail 315, and a second voltage rail 316. In various examples, data may be written to the first and second storage nodes 310a, 310b. The data may be read by the read circuit 302. The data may have a logic high value or a logic low value. The logic high value may correspond to a binary bit value of 1. The logic low value may correspond to a binary bit value of 0.

The passgate transistor 304 includes drain and source terminals electrically connected between the second storage node 310b and the bit line 305. A gate terminal of the passgate transistor 304 is electrically connected to the word write line 312. In various examples, the word write line 312 may activate the passgate transistor 304. When activated, the passgate transistor 304 may pass data from the bit line 305 to the storage node 310b. It would be appreciated by one of ordinary skill in the art that the passgate transistor 304 may be electrically connected to either the first storage node 310a or the second storage node 310b without departing from the scope of the disclosure. In various examples, the word write line 312 may activate the passgate transistor 304 to store data in the second storage node 310b. Data stored in the first storage node 310a may have a complementary value to the data stored in the storage node 310b.

The first pair of p-channel transistors 306a, 306b are electrically connected in series between the first voltage rail 315 and the second storage node 310b. The first pair of n-channel transistors are electrically connected in series between the second storage node 310b and the second voltage rail 316. A drain terminal of the p-channel transistor 306a is electrically connected to a source terminal of the p-channel transistor 306b. A source terminal of the p-channel transistor 306a is electrically connected to the voltage rail 315. The first pair of n-channel transistors 307a, 307b are electrically connected to each other in series. A source terminal of the n-channel transistor 307a is electrically connected to a drain terminal of the n-channel transistor 307b. A source terminal of the n-channel transistor 307b is electrically connected to the voltage rail 316. A drain terminal of the p-channel transistor 306b is electrically connected to a drain terminal of the n-channel transistor 307a to define the second storage node 310b.

The p-channel transistor 308 is electrically connected between the first voltage rail 315 and the first storage node 310a. The n-channel transistor 309 is electrically connected between the first storage node 310a and the second voltage rail 316. A source terminal of the p-channel transistor 308 is electrically connected to the voltage rail 315. A drain terminal of the p-channel transistor 308 is electrically connected to a drain terminal of the n-channel transistor 309. A source terminal of the n-channel transistor 309 is electrically connected to the voltage rail 316. The drain terminal of the p-channel transistor 308 being electrically connected to the drain terminal of the n-channel transistor 309 may define the first storage node 310a.

In various examples, respective gate terminals of the first pair of p-channel transistors 306a, 306b and the n-channel transistors 307a, 307b are electrically connected together and electrically connected to the first storage node 310a. Respective gate terminals of the p-channel transistor 308 and the n-channel transistor 309 are electrically connected together and electrically connected to the second storage node 310b.

When data is written to the second storage node 310b by the passgate transistor 304, the data may cause either the third p-channel transistor 308 or the third n-channel transistor 309 to be activated. Accordingly, the data stored in the storage nodes 310a, 310b may have complementary values. When the data has the logic low value, the third p-channel transistor 308 may be activated and the n-channel transistor third n-channel transistor 309 may be deactivated. When the data has the logic high value, the n-channel transistor 309 may be activated and the third p-channel transistor 308 may be deactivated. When the third p-channel transistor 308 is activated, data having a logic high value may be passed from the voltage rail 315 to the storage node 310a. When the third n-channel transistor 309 is activated, data having the logic low value may be passed from the voltage rail 316 to the storage node 310a. It would be appreciated by one of ordinary skill in the art that the passgate transistor may be electrically connected to the storage node 310a without departing from the scope of the present disclosure.

In various examples, the read circuit 302 includes a first read transistor 303a and a second read transistor 303b. The first and second read transistors 303a, 303b may be electrically connected together in series. In various examples, two transistors may be electrically connected in series when a drain terminal of a first transistor is electrically connected to a source terminal of a second transistor. A source terminal of the first read transistor 303a may be electrically connected to a voltage rail, such as the voltage rail 315. The voltage rail 315 may provide one of a supply voltage Vdd and a ground voltage to the first read transistor 303a, as discussed below with reference to FIGS. 4A-4D. A gate terminal of the second read transistor 303b may be electrically connected to the word read line 314. A drain of the second read transistor 303b may be electrically connected to the bit line 305.

The first read transistor 303a may be activated or deactivated depending on a value of the data stored in the first storage node 310a. In an example, the first read transistor 303a may be a p-channel transistor. The first read transistor 303a may be activated when data having the logic low value is stored in the first storage node 310a. The first read transistor 303a may be deactivated when data having the logic high value is stored in the first storage node 310a. The second read transistor 303b may be activated to read the data from the first storage node 310a. The second read transistor 303b may pass the data to the bit line 305. The bit line 305 may connect the signal to another device, such as another memory cell or an FPGA.

The second read transistor 303b may pass data having a logic high value when the first read transistor 303a is deactivated. The second read transistor 303b may pass data having the logic low value when the read transistor 303a is activated. Accordingly, the data may be read based on whether the first read transistor 303a is activated or deactivated. Advantageously, data may be read from the first storage node 310a without disturbing the first storage node 310a. In various examples, because the data stored in the first and second storage nodes 310a, 310b has complementary values, data read from the storage node 310a may be used to determine the value of the data stored in the second storage node 310b. Accordingly, only the data from the first storage node 310a needs to be read to determine the value of the data stored in both storage nodes 310a, 310b.

In various examples, each of the p-channel transistors 306a, 306b, 308, the n-channel transistors 307a, 307b, 309, passgate transistor 304, and read transistors 303a, 303b may occupy about 3 nm of space when disposed on a die, without limitation. The passgate transistor 304 may occupy a die area of 3 nm. The first pair of p-channel transistors 306a, 306b may occupy a die area of 3 nm each, or 6 nm total. The p-channel transistor 308 may occupy a die area of 3 nm. The first pair of n-channel transistors 307a, 307b may occupy a die area of 3 nm each, or 6 nm total. The n-channel transistor 309 may occupy a die area of 3 nm. It would be appreciated by one of ordinary skill in the art that the transistors may occupy more or less die area, depending on a type of transistor that is used.

In various examples, the logic high value may correspond to a voltage Vdd. In various examples, the voltage Vdd may be 0.7V, 0.6V, 0.5V, or 0.4V, without limitation. A threshold voltage of each of the p-channel transistors 306a, 306b, 308, the n-channel transistors 307a, 307b, 309, passgate transistor 304, and read transistors 303a, 303b may be selected based on a desired value of the voltage Vdd. In an example, when Vdd is 0.4V, the threshold voltage may be around 0.15V, without limitation.

In various examples, when the passgate transistor 304 is activated, a current passing through the passgate transistor 304 may overpower any current flowing through the p-channel transistors 306a, 306b, or the n-channel transistors 307a, 307b, which may allow data to be stored in the storage nodes 310a, 310b while preventing leakage between the various transistors of the 9T memory cell 300. The series arrangement of the p-channel transistors 306a, 306b and n-channel transistors 307a, 307b may be referred to as a cascoded scheme. The cascoded scheme of the transistors may prevent signal leakage and reduce static power consumption.

In various examples, the first storage node 310a and the second storage node 310b may store complementary values. For example, when the data stored in the first storage node 310a is the logic high value, the data stored in the second storage node 310b may be the logic low value, as described above. Data may be written to the storage nodes 310a, 310b at any time and without restriction due to the word write line 312 being independent of the word read line 314. The read circuit 302 may enable a read operation to be performed independently of a write operation. Separation of the read and write operations may enable the read operations and write operations to be performed any time, without limitation.

In various examples, the read circuit 302 may enable data to be read from the first storage node 310a and the second storage node 310b at any time. Separation of the write operations and read operations may enable data to be read from the first storage node 310a and the second storage node 310b without causing read disturb at the first storage node 310a or the second storage node 310b. Additionally, the inclusion of the dedicated read circuit 302 may enable detection of read disturb at the first storage node 310a and the second storage node 310b and enable background read and repair of the 9T memory cell 300 when read disturb is detected. The 9T memory cell 300 may have reduced power consumption while providing independent read and write operations.

FIGS. 4A-4D illustrate various read circuits for use with a memory cell, such as the memory cells described with reference to FIGS. 1-3. In various examples, any of the read circuits shown in FIGS. 4A-4D may be used with any of the memory cells shown in FIGS. 1-3. Each read circuit may include a first read transistor and a second read transistor electrically connected in series. A gate terminal of the first read transistor may be electrically connected to a storage node of a memory cell, as discussed with reference to FIGS. 1-3. A gate terminal of the second read transistor may be electrically connected to a word write line, such as the word write line 114 of FIG. 1, the word write line 214 of FIG. 2, or the word write line 314 of FIG. 3, without limitation.

Referring to FIG. 4A, a read circuit 400a includes a first p-channel read transistor 402a and a second p-channel read transistor 404a. The first read transistor 402a includes a source terminal electrically connected to a voltage rail 406a. The voltage rail 406a may supply a voltage Vdd. A gate terminal of the first read transistor 402a may be electrically connected to a storage node of the memory cell. A drain terminal of the first read transistor 402a may be electrically connected to a source terminal of the second read transistor 404a. A drain terminal of the second read transistor 404a may be electrically connected to a bit line 410. In various examples, the bit line 410 may be the bit line 105a of FIG. 1, the bit line 205c of FIG. 2, or the bit line 305 of FIG. 3, without limitation. A gate terminal of the second read transistor 404a may be electrically connected to a word write line 408. The word write line 408 may be the word write line 114 of FIG. 1, the word write line 214 of FIG. 2, or the word write line 314 of FIG. 3, without limitation. When implemented in a memory cell, the first and second p-channel read transistors 402a and 404a may enable the memory cell to have a compact configuration due to equal numbers of p-channel transistors and n-channel transistors being included in the memory cell.

Data may be read from the storage node by activating the second read transistor 404a. The data stored in the storage node may cause the first read transistor 402a to be activated or deactivated, depending on whether the data has a logic high value or a logic low value. The logic high value may correspond to a binary bit value of 1. The logic low value may correspond to a binary bit value of 0. When the data has the logic low value, the first read transistor 402a may be activated such that when the second read transistor 404a is activated, the logic low value will be passed to the bit line 410. When the data has the logic high value, the first read transistor 402a may be deactivated, such that when the second read transistor 404a is activated, the logic high value will be passed to the bit line 410. Accordingly, the data from the storage node may be read without disturbing the storage node. The value of the data may be read based on whether the first read transistor 402a is activated or deactivated.

Referring to FIG. 4B, a read circuit 400b includes a first p-channel read transistor 402b and a second n-channel read transistor 404b. The first read transistor 402b includes a source terminal electrically connected to a voltage rail 406b. The voltage rail 406b may be a ground terminal. A gate terminal of the first read transistor 402b may be electrically connected to a storage node of the memory cell, as discussed with reference to FIGS. 1-3. A drain terminal of the first read transistor 402b may be electrically connected to a source terminal of the second read transistor 404b. A drain terminal of the second read transistor 404b may be electrically connected to the bit line 410. A gate terminal of the second read transistor 404b may be electrically connected to the word write line 408. In various examples, the first p-channel read transistor 402b and the second n-channel read transistor 404b may occupy additional space than the examples of FIGS. 4A and 4D when disposed on a die. The first p-channel read transistor 402b and the second n-channel read transistor 404b may have reduced signal leakage compared to the examples of FIGS. 4A and 4D.

Data may be read from the storage node by activating the second read transistor 404b. The data stored in the storage node may cause the first read transistor 402b to be activated or deactivated, depending on whether the data has a logic high value or a logic low value. The logic high value may correspond to a binary bit value of 1. The logic low value may correspond to a binary bit value of 0. When the data has the logic low value, the first read transistor 402b may be activated, such that when the second read transistor 404b is activated, the logic low value will be passed to the bit line 410. When the data has the logic high value, the first read transistor 402b may be deactivated, such that when the second read transistor 404b is activated, the logic high value will be passed to the bit line 410. Accordingly, the data from the storage node may be read without disturbing the storage node. The value of the data may be read based on whether the first read transistor 402b is activated or deactivated.

Referring to FIG. 4C, a read circuit 400c includes a first p-channel read transistor 402c and a second n-channel read transistor 404c. The first read transistor 402c includes a source terminal electrically connected to a voltage rail 406c. The voltage rail 406c may supply a voltage Vdd. A gate terminal of the first read transistor 402c may be electrically connected to a storage node of the memory cell, as discussed with reference to FIGS. 1-3. A drain terminal of the first read transistor 402c may be electrically connected to a source terminal of the second read transistor 404c. A drain terminal of the second read transistor 404c may be electrically connected to the bit line 410. A gate terminal of the second read transistor 404c may be electrically connected to the word write line 408. In various examples, the first p-channel read transistor 402c and the second n-channel read transistor 404c may occupy additional space than the examples of FIGS. 4A and 4D when disposed on a die. The first p-channel read transistor 402c and the second n-channel read transistor 404c may have reduced signal leakage compared to the examples of FIGS. 4A and 4D.

Data may be read from the storage node by activating the second read transistor 404c. The data stored in the storage node may cause the first read transistor 402c to be activated or deactivated, depending on whether the data has a logic high value or a logic low value. The logic high value may correspond to a binary bit value of 1. The logic low value may correspond to a binary bit value of 0. When the data has the logic low value, the first read transistor 402c may be activated, such that when the second read transistor 404c is activated, the logic low value will be passed to the bit line 410. When the data has the logic high value, the first read transistor 402c may be deactivated, such that when the second read transistor 404c is activated, the logic high value will be passed to the bit line 410. Accordingly, the data from the storage node may be read without disturbing the storage node. The value of the data may be read based on whether the first read transistor 402c is activated or deactivated.

Referring to FIG. 4D, a read circuit 400d includes a first n-channel read transistor 402d and a second n-channel read transistor 404d. The first read transistor 402d includes a source terminal electrically connected to a voltage rail 406d. The voltage rail 406d may be a ground terminal. A gate terminal of the first read transistor 402d may be electrically connected to a storage node of the memory cell, as discussed with reference to FIGS. 1-3. A drain terminal of the first read transistor 402d may be electrically connected to a source terminal of the second read transistor 404d. A drain terminal of the second read transistor 404d may be electrically connected to the bit line 410. A gate terminal of the second read transistor 404d may be electrically connected to the word write line 408. In various examples, the first and second n-channel read transistors 402d, 404d may occupy additional space than the examples of FIGS. 4A and 4C when disposed on a die. The first and second n-channel read transistors 402d, 404d may have reduced signal leakage compared to the examples of FIGS. 4A and 4C.

Data may be read from the storage node by activating the second read transistor 404d. The data stored in the storage node may cause the first read transistor 402d to be activated or deactivated, depending on whether the data has a logic high value or a logic low value. The logic high value may correspond to a binary bit value of 1. The logic low value may correspond to a binary bit value of 0. When the data has the logic low value, the first read transistor 402d may be deactivated, such that when the second read transistor 404d is activated, the logic low value will be passed to the bit line 410. When the data has the logic high value, the first read transistor 402d may be activated, such that when the second read transistor 404d is activated, the logic high value will be passed to the bit line 410. Accordingly, the data from the storage node may be read without disturbing the storage node. The value of the data may be read based on whether the first read transistor 402d is activated or deactivated.

It would be appreciated by one of ordinary skill in the art that other combinations of read transistors may be possible. For example, the first read transistor may be an n-channel transistor and the second read transistor may be a p-channel transistor.

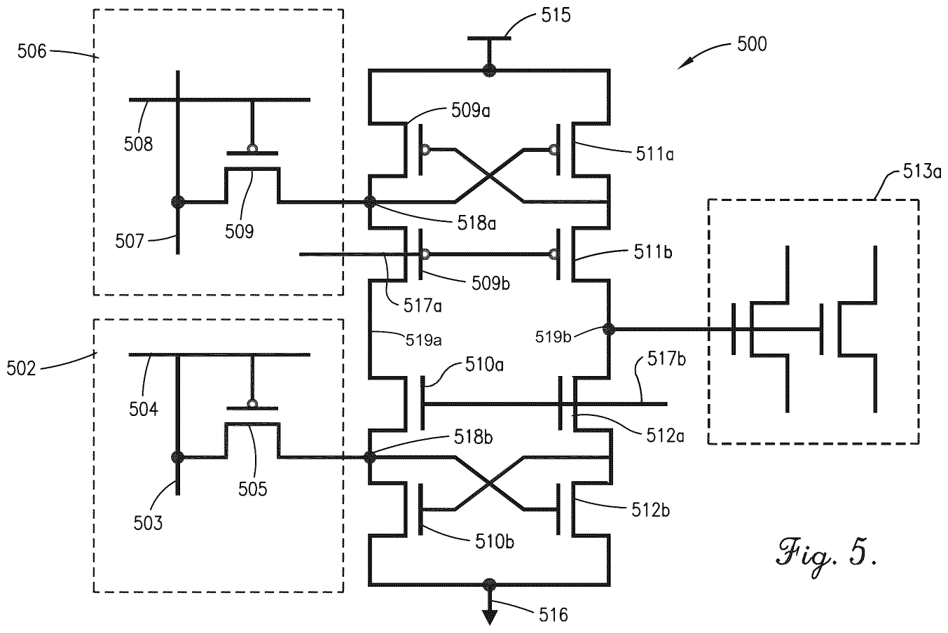

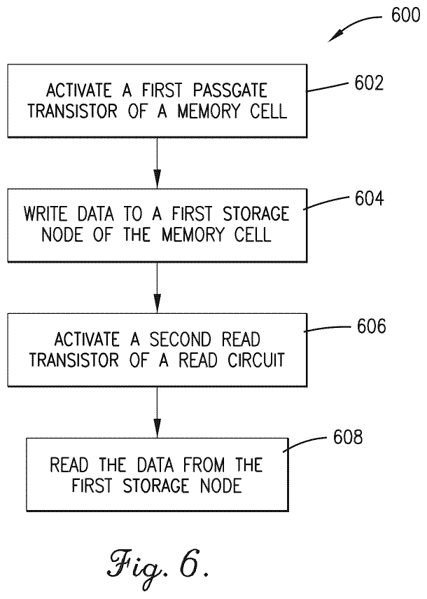

FIG. 5 illustrates an example ten transistor (10T) memory cell 500 having a dedicated read circuit 502. The 10T memory cell additionally includes a dedicated write circuit 506, a first pair of p-channel transistors 509a, 509b, a first pair of n-channel transistors 510a, 510b, a second pair of p-channel transistors 511a, 511b, a second pair of n-channel transistors 512a, 512b, a first voltage rail 515, and a second voltage rail 516. The memory cell 500 additionally includes a first storage node 519a and second storage node 519b. An output from the first storage node 519a may drive a circuit 513a. The circuit 513a may correspond to a switch of a reprogrammable device, such as an FPGA.

In various examples, the read circuit 502 may include a bit read line 503 and a word read line 504, and a read transistor 505. The read transistor 505 may be a p-channel transistor. The word read line 504 may be electrically connected to a gate terminal of the p-channel transistor 505. The word read line 504 may activate the p-channel transistor 505 to read data from one of the storage nodes 519a, 519b. The p-channel transistor 505 may have a source terminal electrically connected to the bit read line 503. The data may be passed from the read transistor 505 to the bit read line 503. A drain terminal of the read transistor 505 may be electrically connected to an intermediate node 518b. The read transistor 505 may read the data from one of the storage nodes 519a, 519b through the intermediate node 518b. Reading the data through the intermediate node 518b may reduce read disturb errors by reading the data from the storage nodes 519a, 519b without having a direct connection to the storage nodes 519a, 519b. As used herein, a “direct connection” between a first electrical component and a second electrical component may refer to an electrical contact or terminal of the first electrical component physically touching an electrical contact or terminal of the second electrical component to enable the exchange electrical energy between the first electrical component and the second electrical component. In various examples, the physical connection of a direct connection is not interrupted by any intervening electrical component, such as a capacitor, transistor, resistor, inductor, and switch, without limitation. In various examples, the physical connection of the direct connection may be formed by the respective contacts and terminals of the two directly connected electrical components via a conductive wire or terminal. In various examples, more than two electronic components may have direct connections with each other, such as the drain terminal of the read transistor 505 being directly connected to the source of the n-channel transistor 510a and the drain terminal of the n-channel transistor 510b.

In various examples, the write circuit 506 includes a bit write line 507, a word write line 508, and a write transistor 509. The word write line 508 may be electrically connected to a gate terminal of the write transistor 509. The word write line 508 may activate the write transistor 509 to write data to one of the storage nodes 519a, 519b. The bit write line 507 may be electrically connected to a drain terminal of the p-channel transistor 509 and may pass data to be stored in one of the storage nodes 519a, 519b through the p-channel transistor 509. A source terminal of the p-channel transistor may be electrically connected to an intermediate node 518a. Data may be written to one of the storage nodes 519a, 519b through the intermediate node 518a.

It would be appreciated by one of ordinary skill in the art that the read circuit 502 and the write circuit 506 may be interchangeable. In an example, the read circuit 502 may be electrically connected to the intermediate node 518a and the write circuit 506 may be electrically connected to the intermediate node 518b. Further, the read and write transistors 505, 509 may be n-channel transistors without departing from the scope of the present disclosure.

The first pair of p-channel transistors 509a, 509b are electrically connected in series between the first voltage rail 515 and the second storage node 519b. The first pair of n-channel transistors 510a, 510b are electrically connected in series between the second storage node 519b and the second voltage rail 516. A drain terminal of the p-channel transistor 509a is electrically connected to a source terminal of the p-channel transistor 509b to define the first intermediate node 518a. A source terminal of the p-channel transistor 509a is electrically connected to the voltage rail 515. The first pair of n-channel transistors 510a, 510b are electrically connected to each other in series. A source terminal of the n-channel transistor 510a is electrically connected to a drain terminal of the n-channel transistor 510b to define the second intermediate node 519b. A source terminal of the n-channel transistor 510b is electrically connected to the voltage rail 516. A drain terminal of the p-channel transistor 509b is electrically connected to a drain terminal of the n-channel transistor 510a to define the second storage node 519b.

The second pair of p-channel transistors 511a, 511b are electrically connected in series between the first voltage rail 515 and the first storage node 519a. The second pair of n-channel transistors 512a are electrically connected in series between the first storage node 519a and the second voltage rail 516. A source terminal of the p-channel transistor 511a is electrically connected to the voltage rail 515. A drain terminal of the p-channel transistor 511a is electrically connected to a source terminal of the p-channel transistor 511b to define a third intermediate node. A drain terminal of the p-channel transistor 511b is electrically connected to a drain terminal of the n-channel transistor 512a. A source terminal of the n-channel transistor 512a is electrically connected to a drain terminal of the n-channel transistor 512b to define a fourth intermediate node. In some examples, the write circuit 506 may be electrically connected to the third intermediate node and the read circuit 502 may be electrically connected to the fourth intermediate node. A source terminal of the n-channel transistor 512b is electrically connected to the voltage rail 516. The drain terminal of the p-channel transistor 511b being electrically connected to the drain terminal of the n-channel transistor 512a may define the first storage node 519a.

The memory cell 500 may additionally include a p-channel protection line 517a and an n-channel protection line 517b. The p-channel protection line 517a may be electrically connected to gate terminals of the p channel transistors 509b, 511b. The n-channel protection line 517b may be electrically connected to gate terminals of the n-channel transistors 510a, 512a. The p-channel protection line 517a may provide a voltage to activate the p-channel transistors 509b, 511b. The p-channel transistors 509b, 511b may be activated data having a logic low value is written to one of the storage nodes 519a, 519b. The n-channel protection line 517b may provide a voltage to activate the n-channel transistors 510a, 512a. The n-channel transistors 510a, 512a may be activated when data having a logic high value is written to one of the storage nodes 519a, 519b.

In various examples, the storage nodes 519a, 519b may store data having complementary values, such that if a logic high value is stored in the first storage node 519a, a logic low value may be stored in the second storage node 519b. The intermediate node 518a may be electrically connected to a gate terminal of the p-channel transistor 511a. A gate terminal of the p-channel transistor 509a may be electrically connected to an intermediate node between the source terminal of the p-channel transistor 511a and the drain terminal of the p-channel transistor 511b. Data that is passed from the write circuit 506 to the intermediate node 518a may activate or deactivate the p-channel transistor 511a. In an example, data having the logic low value may activate the p-channel transistor 511a, which will cause the p-channel transistor 509a to be activated, which allows the data to be stored in the storage node 519b. The logic low value being stored in the storage node 519b may cause data having the logic high value to be stored in the storage node 519a.

In various examples, the transistors 509a, 509b, 510a, 510b, 511a, 511b, 512a, 512b may be standard logic devices. The voltage rail 515 may provide a voltage Vdd. Due to the cascoded configuration of the transistors 509a, 509b, 510a, 510b, 511a, 511b, 512a, 512b, an output provided to the circuit 513a from the storage node 519b may have a voltage of 2Vdd. The p-channel protect line 517a and the n-channel protect line 517b may alter a bias voltage of the memory cell while ensuring the voltage drop across the transistors 509a, 509b, 510a, 510b, 511a, 511b, 512a, 512b does not exceed the voltage Vdd.

In various examples, the logic high value may correspond to a voltage Vdd. In various examples, the voltage Vdd may be 0.7V, 0.6V, 0.5V, or 0.4V, without limitation. A threshold voltage of each of the transistors 509a, 509b, 510a, 510b, 511a, 511b, 512a, 512b may be selected based on a desired value of the voltage Vdd. In an example, when Vdd is 0.4V, the threshold voltage may be around 0.15V, without limitation.

FIG. 6 illustrates a method 600 for operating a memory cell. In various examples, the memory cell may be any of the memory cells described with references to FIGS. 1, 2, 3, and 5, without limitation. At operation 602, a first passgate transistor of the memory cell may be activated. A gate terminal of the first passgate transistor may be electrically connected to a word write line. The word write line may activate the first passgate transistor by supplying a voltage to the gate terminal of the first passgate transistor.

At operation 604, in response to activation of the first passgate transistors, data may be written to a first storage node of the memory cell. In various examples, the first storage node may be any one of the storage nodes 110a, 110b shown in FIG. 1, the storage nodes 210a, 210b shown in FIG. 2, the storage nodes 310a, 310b shown in FIG. 3, or the storage node associated with the write circuit 506 shown in FIG. 5, without limitation. A drain terminal of the first passgate transistor may be electrically connected to a first bit line. The first bit line may pass data to the first passgate transistor. A source terminal of the first passgate transistor may be electrically connected to the first storage node. When activated, the passgate transistor may pass the data to the first storage node from the first bit line. The data may be stored in the first storage node. In various examples, the memory cell may include a second storage node. The second storage node may store data having a complementary value to data stored in the first storage node, such that if a logic high signal is stored in the first storage node, a logic low signal may be stored in the second storage node.

In various examples, the memory cell may include a read circuit. In various examples, the read circuit may be one of the read circuits 400a, 400b, 400c, 400d shown in FIG. 4, without limitation. The read circuit may include a first read transistor and a second read transistor. A drain terminal of the first read transistor may be electrically connected to a source terminal of the second read transistor. A gate terminal of the first read transistor may be electrically connected to one of the first storage node and the second storage node. In an example, the first read transistor may be electrically connected to the first storage node. The read circuit may additionally include a second read transistor electrically connected in series with the first read transistor.

The data stored in the first storage node may activate or deactivate the first read transistor depending on whether the data has a logic high value or a logic low value. The logic high value may correspond to a binary value of 1. The logic low value may correspond to a binary value of 0. In some examples, data having the logic high value may deactivate the first read transistor and data having the logic low value may activate the first read transistor. In other examples, data having the logic high value may activate the first read transistor and data having the logic low value may deactivate the first read transistor. The second read transistor may be activated to output the value of the data based on whether the first read transistor is activated or deactivated. Accordingly, data may be read from the storage node without disturbing the storage node.

In various examples, the memory cell may include a first voltage rail, a second voltage rail, a first storage node, a first pair of p-channel transistors, and a first pair of n-channel transistors. The first pair of p-channel transistors may be electrically connected together in series between the first voltage rail and the second storage node. Respective gate terminals of the first pair of p-channel transistors may be electrically connected to the first storage node. The first pair of n-channel transistors may be electrically connected together in series between the second storage node and the second voltage rail. Respective gate terminals of the first pair of n-channel transistors may be electrically connected to the first storage node. In various examples, data may be written to the second storage node by activating one of the first pair of p-channel transistors and the first pair of n-channel transistors. The first pair of p-channel transistors or the first pair of n-channel transistors may be activated based on a value of the data stored in the first storage node and in response to data being written to the first storage node. In an example, if the data has the logic high value, the first pair of n-channel transistors may be activated. If the data has the logic low value, the first pair of p-channel transistors may be activated.

When the first pair of p-channel transistors are activated, data corresponding to the logic high value may be passed from the first voltage rail to the second storage node. When the first pair of n-channel transistors are activated, data having the logic low value may be passed from the second voltage rail to the second storage node. Accordingly, the data stored in the first and second storage nodes may be complementary.

In an example, the memory cell may include a second passgate transistor, a second pair of p-channel transistors, and a second pair of n-channel transistors. A gate terminal of the second passgate transistor may be electrically connected to the word write line. The second pair of p-channel transistors may be electrically connected in series between the first voltage rail and the first storage node. Respective gate terminals of the first pair of p-channel transistors may be electrically connected to the second storage node. The second pair of n-channel transistors may be electrically connected in series between the first storage node and the second voltage rail. Respective gate terminals of the second pair of n-channel transistors may be electrically connected to the second storage node. When data is written to the first storage node, one of the first pair of p-channel transistors and the first pair of n-channel transistors may be activated, as described above. Accordingly, data being written to the second storage node may cause one of the second pair of n-channel transistors and the second pair of p-channel transistors to be activated and cause complementary data to be stored in the first storage node.

The second passgate transistor may be activated and, in response to being activated, pass data to be stored in the second storage node. The second pair of p-channel transistors or the second pair of n-channel transistors may be activated based on a value of the data. If the data has the logic high value, the first pair of n-channel transistors may be activated. Data having the logic low value may be passed from the second voltage rail to the first storage node. If the data has the logic low value, the first pair of p-channel transistors may be activated. Data having the logic high value may be passed from the first voltage rail to the first storage node. The first and second storage nodes may have complementary values due to data being written to one storage node causing complementary data to be stored in the second storage node. Accordingly, only one of the passgate transistors is needed to write data to both the first and second storage nodes.

In another example, the memory cell may include a third p-channel transistor electrically connected between the first voltage rail and the first storage node and a third n-channel transistor electrically connected between the first storage node and the second voltage rail. Respective gate terminals of the third p-channel transistor and the third n-channel transistor may be electrically connected to the second storage node. When data is written to the first storage node, one of the first pair of p-channel transistors and the first pair of n-channel transistors may be activated to store a complementary value in the second storage node, as described above. Similarly, data written to the second storage node may cause one of the third n-channel transistor and the third p-channel transistor to be activated. Accordingly, the first and second storage nodes may store data having complementary values.

At operation 606, the second read transistor may be activated by a word read line. Activating the second read transistor may cause the read circuit to produce an output signal indicating a value of the data stored in the first storage node. The second read transistor may pass a logic high value or a logic low value depending on whether the first read transistor is activated, as described above.

At operation 608, the data may be read from the first storage node in response to activating the second read transistor. The output signal may be provided to a second bit line. In various examples, the second bit line may be the same as the first bit line. In other examples, the second bit line may be a dedicated read bit line separate from the first bit line. The second bit line may provide the output signal to another device, such as another memory cell or an FPGA.

In various examples, the first read transistor may be a p-channel transistor or an n-channel transistor. The second read transistor may be a p-channel transistor or an n-channel transistor. A source terminal of the first read transistor may be electrically connected to a voltage rail. The voltage rail may be a ground terminal or a supply voltage. Reading data from the first storage node may include activating or deactivating the first read transistor based on a value of data stored in the first storage node. The second read transistor may output the value of data as an output signal.

In various examples, the memory cell may include a second bit line and a second passgate transistor. A gate terminal of the second passgate transistor may be electrically connected to the word write line. The second passgate transistor may be electrically connected between the second bit line and the second storage node. The second passgate transistor may write data to the second storage node. The first passgate transistor may be electrically connected between the first bit line and the first storage node. Reading data from the first storage node may include activating or deactivating the first read transistor based on a value of the data stored in the first storage node. The second read transistor may output the value of data as an output signal to the second bit line. The second bit line may connect the output signal to another device, such as another memory cell or an FPGA.

In another example, the memory cell may include a second bit line, a second passgate transistor, and a third bit line. A gate terminal of the second passgate transistor may be electrically connected to the word write line. The second passgate transistor may be electrically connected between the second bit line and the second storage node. The second passgate transistor may write data to the second storage node. The first passgate transistor may be electrically connected between the first bit line and the first storage node. Reading data from the first storage node may include activating the first read transistor by the first passgate transistor or the data stored in the first storage node. The second read transistor may output the data as an output signal to the third bit line. The third bit line may connect the output signal to another device, such as another memory cell or an FPGA.

In various examples, the logic high value may correspond to a voltage Vdd. In various examples, the voltage Vdd may be 0.7V, 0.6V, 0.5V, or 0.4V, without limitation. A threshold voltage of each of the p-channel transistors, the n-channel transistors, passgate transistor(s), and read transistor(s) may be selected based on a desired value of the voltage Vdd. In an example, when Vdd is 0.4V, the threshold voltage may be around 0.15V, without limitation.

According to various examples of the present disclosure, a memory cell may be provided. The memory cell may include a word write line, a first bit line, a first storage node, a second storage node, a first passgate transistor, and a read circuit. The first passgate transistor includes a gate terminal, a source terminal, and a drain terminal. The gate terminal of the first passgate transistor may be electrically connected to the word write line. The source terminal of the first passgate transistor may be electrically connected to the first bit line. The drain terminal of the first passgate transistor may be electrically connected to one of the first and second storage nodes. The read circuit may include a word read line, a first read transistor, and a second read transistor. The first and second read transistors include respective gate, source and drain terminals. The gate terminal of the first read transistor may be electrically connected to the first storage node. The gate terminal of the second read transistor may be electrically connected to the word read line. The drain terminal of the first read transistor may be electrically connected to the source terminal of the second read transistor.

In combination with any of the previous examples, the memory cell may include a first voltage rail, a second voltage rail, a first pair of p-channel transistors, and a first pair of n-channel transistors. The first pair of p-channel transistors may be electrically connected in series between the first voltage rail and the second storage node. The first pair of p-channel transistors may include respective gate terminals electrically connected to the first storage node. The first pair of n-channel transistors may be electrically connected in series between the second storage node and the second voltage rail. The first pair of n-channel transistors may include respective gate terminals electrically connected to the first storage node.

In combination with any of the previous examples, the memory cell may include a second passgate transistor, a second pair of p-channel transistors, and a second pair of n-channel transistors. The second passgate transistor may include a gate terminal electrically connected to the word write line. The second pair of p-channel transistors may be electrically connected in series between the first voltage rail and the first storage node. The second pair of p-channel transistors may include respective gate terminals electrically connected to the second storage node. The second pair of n-channel transistors may be electrically connected in series between the first storage node and the second voltage rail. The second pair of n-channel transistors may include respective gate terminals electrically connected to the second storage node.

In combination with any of the previous examples, the memory cell may include a third p-channel transistor and a third n-channel transistor. The third p-channel transistor may be electrically connected between the first voltage rail and the first storage node. The third p-channel transistor may include a gate terminal electrically connected to the second storage node. The third n-channel transistor may be electrically connected between the first storage node and the second voltage rail. The third n-channel transistor may include a gate terminal electrically connected to the second storage node.

In combination with any of the previous examples, the first and second read transistors may be p-channel transistors. The source terminal of the first read transistor may be electrically connected to a voltage rail.

In combination with any of the previous examples, the first and second read transistors may be n-channel transistors. The source terminal of the first read transistor may be electrically connected to ground.

In combination with any of the previous examples, the first read transistor may be a p-channel transistor. The second read transistor may be an n-channel transistor. The source terminal of the first read transistor may be electrically connected to a voltage rail.

In combination with any of the previous examples, the first read transistor may be an n-channel transistor. The second read transistor may be a p-channel transistor. The source terminal of the first read transistor may be electrically connected to ground.

In combination with any of the previous examples, the memory cell may include a second bit line and a second passgate transistor. The second passgate transistor may include a gate terminal electrically connected to the word write line. The second passgate transistor may be electrically connected between the second bit line and the second storage node. The drain terminal of the second read transistor may be electrically connected to the second bit line.

In combination with any of the previous examples, the memory cell may include a second bit line, a second passgate transistor, and a third bit line. The second passgate transistor may include a gate terminal electrically connected to the word write line. The second passgate transistor may be electrically connected between the second bit line and the second storage node. The drain terminal of the second read transistor may be electrically connected to the third bit line.

According to various examples of the present disclosure, a method may be provided. A word write line may activate a first passgate transistor of a memory cell. The first passgate transistor may have a drain terminal electrically connected to a first storage node of the memory cell. A first bit line of the memory cell may write data to the first storage node. The first storage node may be electrically connected to a read circuit of the memory cell. The read circuit may include a first read transistor and a second read transistor. A drain terminal of the first read transistor may be electrically connected to a source terminal of the second read transistor. A word read line of the memory cell may activate the second read transistor of the read circuit. The data may be read from the first storage node.

In combination with any of the previous examples, a gate terminal of the first read transistor may be electrically connected to the first storage node. The memory cell may include a first voltage rail, a second voltage rail, a first storage node, a first pair of p-channel transistors, and a first pair of n-channel transistors. The first pair of p-channel transistors may be electrically connected in series between the first voltage rail and the second storage node. The first pair of p-channel transistors may include respective gate terminals electrically connected to the first storage node. The method may include writing data to the second storage node by activating one of the first pair of p-channel transistors and the first pair of n-channel transistors.

In combination with any of the previous examples, the memory cell may include a second passgate transistor, a second pair of p-channel transistors, and a second pair of n-channel transistors. A gate terminal of the second passgate transistor may be electrically connected to the word write line. The second pair of p-channel transistors may be electrically connected in series between the first voltage rail and the first storage node. The second pair of p-channel transistors may include respective gate terminals electrically connected to the second storage node. The second pair of n-channel transistors may be electrically connected in series between the first storage node and the second voltage rail. The second pair of n-channel transistors may include respective gate terminals electrically connected to the second storage node. Writing, by the first bit line of the memory cell, the data to the first storage node may include activating one of the first pair of p-channel transistors and the first pair of n-channel transistors.

In combination with any of the previous examples, the memory cell may include a third p-channel transistor and a third n-channel transistor. The third p-channel transistor may be electrically connected between the first voltage rail and the first storage node. The third p-channel transistor may include a gate terminal electrically connected to the second storage node. The third n-channel transistor may be electrically connected between the first storage node and the second voltage rail. The third n-channel transistor may include a gate terminal electrically connected to the second storage node. Writing, by the first bit line of the memory cell, the data to the first storage node may include activating one of the first pair of p-channel transistors and the first pair of n-channel transistors.

In combination with any of the previous examples, the first read transistor may be a p-channel transistor or an n-channel transistor. The second read transistor may be a p-channel transistor or an n-channel transistor. A source terminal of the first read transistor may be electrically connected to a voltage rail. Reading the data from the first storage node may include activating or deactivating, based on the value of the data, the first read transistor and outputting, by the second read transistor, the data.

In combination with any of the previous examples, the voltage rail may be a ground terminal or a supply voltage.

In combination with any of the previous examples, the memory cell may include a second bit line, a second storage node, and a second passgate transistor. The second passgate transistor may include a gate terminal electrically connected to the word write line. The second passgate transistor may be electrically connected between the second bit line and the second storage node. The first passgate transistor may be electrically connected between the first bit line and the first storage node. Reading the data from the first storage node may include activating or deactivating, based on a value of the data, the first read transistor and outputting, by the second read transistor, the value of data to the second bit line.

In combination with any of the previous examples, the memory cell may include a second bit line, a second storage node, a second passgate transistor, and a third bit line. The second passgate transistor may include a gate terminal electrically connected to the word write line. The second passgate transistor may be electrically connected between the second bit line and the second storage node. The first passgate transistor may be electrically connected between the first bit line and the first storage node. Reading the data from the first storage node may include activating or deactivating, based on a value of the data, the first read transistor and outputting, by the second read transistor, the value of data to the third bit line.

According to various examples of the present disclosure, a memory cell may be provided. The memory cell may include a first intermediate node, a second intermediate node, a write circuit, a read circuit, a first voltage rail, a second voltage rail, a first storage node, a second storage node, a first pair of p-channel transistor, a second pair of p-channel transistors, a first pair of n-channel transistors, and a second pair of n-channel transistors. The write circuit may include a write word line, a write transistor, and a bit write line. The write transistor may be electrically connected between the bit write line and the first intermediate node. The read circuit may include a read transistor, a word read line, and a bit read line. The read transistor may be electrically connected between the bit read line and the second intermediate node. The first pair of p-channel transistors may be electrically connected in series between the first voltage rail and the first storage node. A drain terminal of a first p-channel transistor of the first pair of p-channel transistors may be electrically connected to a source terminal of a second p-channel transistor of the first pair of p-channel transistors to define the first intermediate node. The second pair of p-channel transistors may be electrically connected in series between the first voltage rail and the second storage node. The first pair of n-channel transistors may be electrically connected in series between the first storage node and the second voltage rail. A drain terminal of a first n-channel transistor of the first pair of n-channel transistors may be electrically connected to a source terminal of a second n-channel transistor of the first pair of n-channel transistors to define the second intermediate node. The second pair of n-channel transistors may be electrically connected in series between the second storage node and the second voltage rail.

In combination with any of the previous examples, the write circuit may write data from the bit line to one of the first and second storage nodes. The read circuit may read data from the one of the first and second storage nodes and provide the data to the bit read line.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

What is claimed is:

1. A memory cell comprising:
a word write line;
a first bit line;
a first storage node;
a second storage node;
a first passgate transistor including a gate terminal, a source terminal, and a drain terminal,
said gate terminal of the first passgate transistor being electrically connected to the word write line,
said source terminal electrically being electrically connected to the first bit line,
said drain terminal of the first passgate transistor being electrically connected to one of the first and second storage nodes; and
a read circuit including a word read line, a first read transistor, and a second read transistor,
said first and second read transistors including respective gate, source, and drain terminals,
said gate terminal of the first read transistor being electrically connected to the first storage node;
said gate terminal of the second read transistor being electrically connected to the word read line,
said drain terminal of the first read transistor electrically connected to the source terminal of the second read transistor.

2. The memory cell of claim 1, comprising
a first voltage rail,
a second voltage rail,
a first pair of p-channel transistors electrically connected in series between the first voltage rail and the second storage node, said first pair of p-channel transistors including respective gate terminals electrically connected to the first storage node,
a first pair of n-channel transistors electrically connected in series between the second storage node and the second voltage rail, said first pair of n-channel transistors including respective gate terminals electrically connected to the first storage node.

3. The memory cell of claim 2, comprising
a second passgate transistor including a gate terminal electrically connected to the word write line,
a second pair of p-channel transistors electrically connected in series between the first voltage rail and the first storage node, said second pair of p-channel transistors including respective gate terminals electrically connected to the second storage node,
a second pair of n-channel transistors electrically connected in series between the first storage node and the second voltage rail, said second pair of n-channel transistors including respective gate terminals electrically connected to the second storage node.

4. The memory cell of claim 2, comprising
a third p-channel transistor electrically connected between the first voltage rail and the first storage node, said third p-channel transistor including a gate terminal electrically connected to the second storage node,
a third n-channel transistor electrically connected between the first storage node and the second voltage rail, said third n-channel transistor including a gate terminal electrically connected to the second storage node.

5. The memory cell of claim 1, wherein
said first and second read transistors are p-channel transistors,
the source terminal of the first read transistor is electrically connected to a voltage rail.

6. The memory cell of claim 1, wherein
said first and second read transistors are n-channel transistors,
the source terminal of the first read transistor is electrically connected to ground.

7. The memory cell of claim 1, wherein
said first read transistor is a p-channel transistor,
said second read transistor is an n-channel transistor,
the source terminal of the first read transistor is electrically connected to a voltage rail.

8. The memory cell of claim 1, wherein
said first read transistor is an n-channel transistor,
said second read transistor is a p-channel transistor,
the source terminal of the first read transistor is electrically connected to ground.

9. The memory cell of claim 1, comprising
a second bit line,
a second passgate transistor including a gate terminal electrically connected to the word write line, said second passgate transistor electrically connected between the second bit line and the second storage node,
wherein said drain terminal of the second read transistor is electrically connected to the second bit line.

10. The memory cell of claim 1, comprising
a second bit line,
a second passgate transistor including a gate terminal electrically connected to the word write line, said second passgate transistor electrically connected between the second bit line and the second storage node,
a third bit line, wherein said drain terminal of the second read transistor is electrically connected to the third bit line.

11. A method comprising:
activating, by a word write line, a first passgate transistor of a memory cell, said first passgate transistor having a drain terminal electrically connected to a first storage node of the memory cell;
writing, by a first bit line of the memory cell, data to the first storage node, said first storage node being electrically connected to a read circuit of the memory cell, said read circuit including a first read transistor and a second read transistor,
a drain terminal of said first read transistor being electrically connected to a source terminal of said second read transistor;
activating, by a word read line of the memory cell, the second read transistor of the read circuit; and
reading the data from the first storage node.

12. The method of claim 11,
wherein a gate terminal of said first read transistor is electrically connected to the first storage node,
wherein the memory cell includes—
a first voltage rail,
a second voltage rail,
a second storage node,
a first pair of p-channel transistors electrically connected in series between the first voltage rail and the second storage node, said first pair of p-channel transistors including respective gate terminals electrically connected to the first storage node,
a first pair of n-channel transistors electrically connected in series between the second storage node and the second voltage rail, said first pair of n-channel transistors including respective gate terminals electrically connected to the first storage node,
wherein the method includes writing data to the second storage node by activating one of the first pair of p-channel transistors and the first pair of n-channel transistors.

13. The method of claim 12, wherein the memory cell includes
a second passgate transistor including a gate terminal electrically connected to the word write line,
a second pair of p-channel transistors electrically connected in series between the first voltage rail and the first storage node, said second pair of p-channel transistors including respective gate terminals electrically connected to the second storage node,
a second pair of n-channel transistors electrically connected in series between the first storage node and the second voltage rail, said second pair of n-channel transistors including respective gate terminals electrically connected to the second storage node,
wherein writing, by the first bit line of the memory cell, the data to the first storage node includes activating one of the first pair of p-channel transistors and the first pair of n-channel transistors.

14. The method of claim 12, wherein the memory cell includes
a third p-channel transistor electrically connected between the first voltage rail and the first storage node, said third p-channel transistor including a gate terminal electrically connected to the second storage node,
a third n-channel transistor electrically connected between the first storage node and the second voltage rail, said third n-channel transistor including a gate terminal electrically connected to the second storage node,
wherein writing, by the first bit line of the memory cell, the data to the first storage node includes activating one of the first pair of p-channel transistors and the first pair of n-channel transistors.

15. The method of claim 11, wherein
said first read transistor is a p-channel transistor or an n-channel transistor,
said second read transistor is a p-channel transistor or an n-channel transistor,
a source terminal of the first read transistor is electrically connected to a voltage rail,
wherein reading the data from the first storage node includes activating or deactivating, based on a value of the data, the first read transistor and outputting, by the second read transistor, the data.

16. The method of claim 15, wherein
said voltage rail is a ground terminal or a supply voltage.

17. The method of claim 11, wherein the memory cell includes
a second bit line,
a second storage node,
a second passgate transistor including a gate terminal electrically connected to the word write line, said second passgate transistor electrically connected between the second bit line and the second storage node,
wherein said first passgate transistor is electrically connected between the first bit line and the first storage node,
wherein reading the data from the first storage node includes activating or deactivating, based on a value of the data, the first read transistor and outputting, by the second read transistor, the value of data to the second bit line.

18. The method of claim 11, wherein the memory cell includes
a second bit line,
a second storage node,
a second passgate transistor including a gate terminal electrically connected to the word write line, said second passgate transistor electrically connected between the second bit line and the second storage node,
a third bit line, wherein said first passgate transistor is electrically connected between the third bit line and the first storage node,
wherein reading the data from the first storage node includes activating or deactivating, based on a value of the data, the first read transistor and outputting, by the second read transistor, a value of the data to the third bit line.

19. A memory cell comprising:
a first intermediate node;
a second intermediate node;
a write circuit including a word write line, a write transistor, and a bit write line, said write transistor being electrically connected between the bit write line and the first intermediate node;
a read circuit including a read transistor, a word read line, and a bit read line, said read transistor being electrically connected between the bit read line and the second intermediate node;
a first voltage rail;
a second voltage rail;
a first storage node;
a second storage node;
a first pair of p-channel transistors electrically connected in series between the first voltage rail and the first storage node, a drain terminal of a first p-channel transistor of the first pair of p-channel transistors being electrically connected to a source terminal of a second p-channel transistor of the first pair of p-channel transistors to define the first intermediate node;
a second pair of p-channel transistors electrically connected in series between the first voltage rail and the second storage node;
a first pair of n-channel transistors electrically connected in series between the first storage node and the second voltage rail, a drain terminal of a first n-channel transistor of the first pair of n-channel transistors being electrically connected to a source terminal of a second n-channel transistor of the first pair of n-channel transistors to define the first intermediate node; and
a second pair of n-channel transistors electrically connected in series between the second storage node and the second voltage rail.

20. The memory cell of claim 19,
said write circuit to write data from the bit write line to one of the first and second storage nodes,
said read circuit to read data from the one of the first and second storage nodes and provide the data to the bit read line.
